(19) United States
(12) Patent Application Publication
(10) Pub. No.: US 2021/0343563 A1
(43) Pub. Date: Nov. 4, 2021

(54) RETICLE POD SEALING

(71) Applicant: ENTEGRIS, INC., Billerica, MA (US)

(72) Inventors: Russ V. RASCHKE, Chanhassen, MN (US); Huaping WANG, Eden Prairie, MN (US)

(21) Appl. No.: 17/244,571

(22) Filed: Apr. 29, 2021

Related U.S. Application Data
(60) Provisional application No. 63/017,825, filed on Apr. 30, 2020.

(51) Int. Cl. H01L 21/673; B65D 85/48; G03F 1/66

(52) U.S. Cl. CPC H01L 21/67376; G03F 1/66; B65D 85/48; H01L 21/67359

(57) ABSTRACT

A pod includes a cover with a cover body, a baseplate with a baseplate body, and one or more seal surfaces. The one or more seal surfaces are formed on one or more of the baseplate body and the cover body to provide sealing. A method of producing a reticle pod includes forming one or more seal surfaces on at least one of a baseplate body of a baseplate and a cover body of a cover. The one or more seal surfaces are formed to provide sealing between the baseplate and the cover. Each of the one or more seal surfaces includes a wear-resistant outermost coating with a Rockwell C hardness of about or greater than 70.

### CROSS-REFERENCE TO RELATED APPLICATION

This application claims the benefit of and priority to U.S. Provisional Application No. 63/017,825 filed on Apr. 30, 2020, which is incorporated herein by reference in its entirety for all purposes.

### FIELD

This disclosure relates to reticle pods used for reticles. More specifically, this disclosure relates to surfaces used to provide sealing in reticle pods.

### BACKGROUND

Reticle pods are used for containing reticles such as, for example, photolithography masks used in semiconductor processing. Reticle pods can be used for storage and transport of reticles. Reticle pods can include a metal inner pod that is handled and manipulated by one or more tools during processing. The inner pod includes a baseplate and a cover, and the baseplate and the cover contain the reticle and protect the reticle from contamination or physical damage during transport, storage, and processing. Reticle pods include, for example, Extreme Ultraviolet (EUV) pods for use with EUV photolithography tools. Reticle pods can include an outer pod with a pod door and a pod dome, which contains the inner pod.

### SUMMARY

This disclosure relates to reticle pods used for reticles. More specifically, this disclosure relates to surfaces used to provide sealing in reticle pods.

In an embodiment, a pod includes a cover with a cover body, a baseplate with a baseplate body, and one or more seal surfaces. The one or more seal surfaces are formed on one or more of the baseplate body and the cover body to provide sealing between the cover and the baseplate. The one or more seal surfaces each include a wear-resistant outermost coating with a Rockwell C hardness of about or greater than 70.

In an embodiment, the wear-resistant outermost coating has a Rockwell C hardness of about or greater than 80.

In an embodiment, the one or more seal surfaces include a first seal surface. The baseplate includes the wear-resistant outermost coating of the first seal surface and the first seal surface is formed on the baseplate body. The wear-resistant outermost coating of the first seal surface is disposed so as to directly contact the cover when the cover is placed on the baseplate.

In an embodiment, the one or more seal surfaces include a second seal surface. The cover includes the wear-resistant outermost coating of the second seal surface and the second seal surface is formed on the cover body. The wear-resistant outermost coating of the cover is disposed so as to directly contact a wear-resistant outermost coating of the baseplate when the cover is placed on the baseplate.

In an embodiment, the pod includes an outer pod dome and an outer pod door. The outer pod dome and the outer pod door are configured to accommodate the baseplate and the cover within the outer pod dome when the outer pod door is attached to the outer pod dome. In an embodiment, the pod is an EUV reticle pod.

In an embodiment, a method of producing a reticle pod includes forming one or more seal surfaces on at least one of a baseplate body of a baseplate and a cover body of a cover. The one or more seal surfaces are formed to provide sealing between the baseplate and the cover. Each of the one or more seal surfaces includes a wear-resistant outermost coating with a Rockwell C hardness of about or greater than 70.

In an embodiment, forming the one or more seal surfaces includes forming a wear-resistant outermost coating on the baseplate body. The wear-resistant outermost coating disposed to directly contact the cover when the cover is placed on the baseplate.

In an embodiment, forming the one or more seal surfaces includes forming a wear-resistant outermost coating on the cover body. The wear-resistant outermost coating disposed to directly contact the baseplate when the cover is placed on the baseplate.

### BRIEF DESCRIPTION OF THE DRAWINGS

The disclosure may be more completely understood in consideration of the following description of various illustrative embodiments in connection with the accompanying drawings

FIG. 1A is a cross-sectional view of an embodiment of an inner pod of a reticle pod.

FIG. 1B is a cross-sectional view of the inner pod in FIG. 1A when open, according to an embodiment.

FIG. 2 is a top view of an embodiment of a baseplate in a reticle pod.

FIG. 3 is a bottom view of an embodiment of a cover for a reticle pod.

FIG. 4 is a cross-sectional view of an embodiment of contacting seal surfaces of a baseplate and a cover for a reticle pod.

FIG. 5 is a prospective view of an embodiment of a reticle pod.

FIG. 6 is a block diagram for an exemplary method of producing a reticle pod.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DETAILED DESCRIPTION

This disclosure is directed to reticle pods used for reticles, and surfaces used to provide sealing within reticle pods.

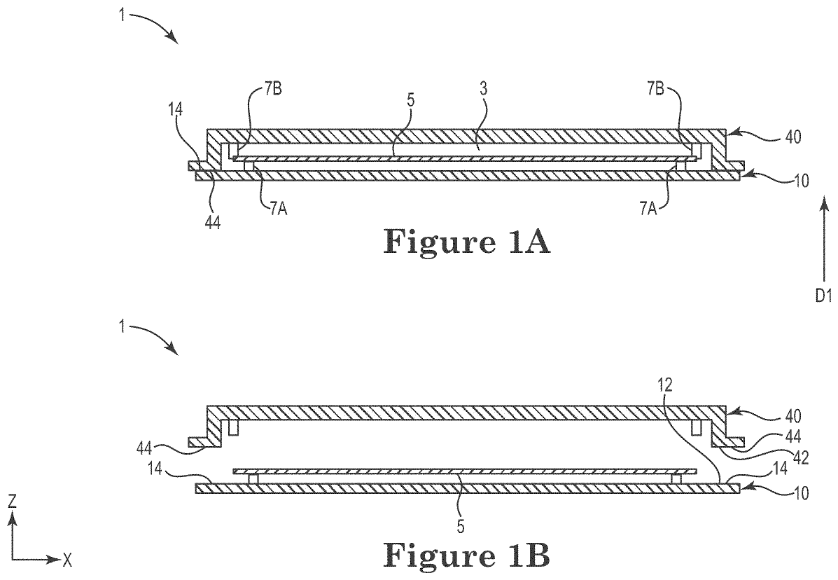

FIGS. 1A and 1B show cross-sectional views of an embodiment of an inner pod 1 of a reticle pod. FIG. 1A shows the inner pod 1 when closed. FIG. 1B shows the inner pod 1 when open. The inner pod 1 has an internal space with a reticle containment portion 3 for containing a reticle 5. The pod 1 can include reticle supports 7A and reticle contacts 7B within the reticle containment portion 3 for supporting and restraining the reticle 5 within the inner pod 1.

The inner pod 1 includes a baseplate 10 and a cover 40. The baseplate 10 and the cover 40 are configured to be joined together. As shown in FIG. 1A, the internal space of the inner pod 1 is enclosed (e.g., closed) by placing the cover 40 on the baseplate 10. The cover 40 directly contacts the baseplate 10. In particular, the bottom 42 of the cover 40 contacts the top 12 of the baseplate 10. The inner pod 1 is opened by moving the cover 40 away from the baseplate 10 (e.g., by moving the cover upwards in direction D₁, etc.). For example, an external tool (e.g., automated arm, etc.) opens the inner pod 1 to access the reticle containment portion 3 and remove the reticle 5.

The baseplate 10 and the cover 40 include one or more seal surface(s) that are configured to provide sealing between the baseplate 10 and the cover 40. For example, the sealing is configured to reduce or prevent external containments (e.g., air, dust, etc.) from entering the pod 1 by passing between the baseplate 10 and the cover 40. The baseplate 10 can includes one or more seal surfaces that directly contact the cover 40 when the cover 40 is placed on the baseplate 10. The cover 40 includes one or more seal surface configured to directly contact the baseplate 10 when the cover 40 is placed on the baseplate 10. For example, the baseplate 10 can include a first seal surface (e.g., seal surface 14) that is configured to directly contact the cover 40, and the cover 40 can include a second seal surface (e.g., seal surface 44) that is configured to directly contact the baseplate 10.

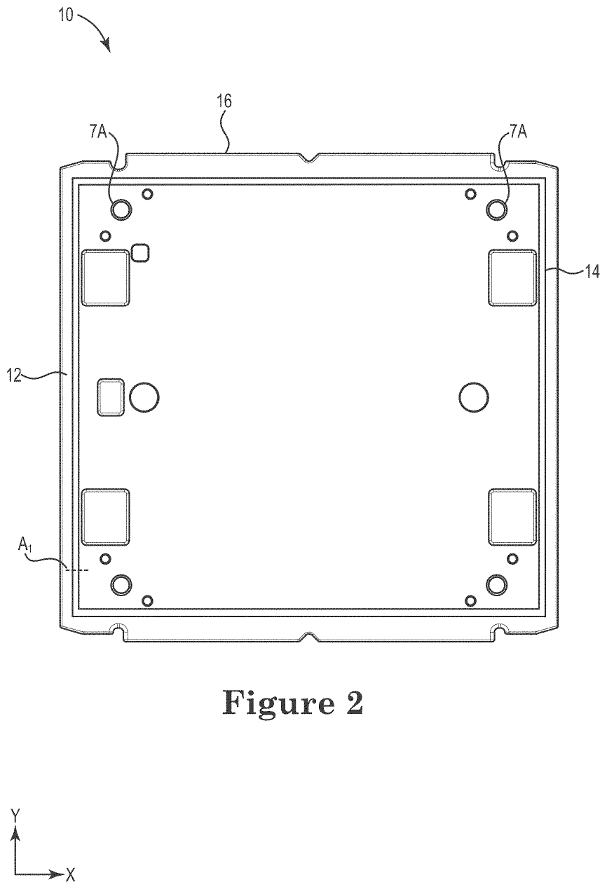

FIG. 2 is a top view of an embodiment of the baseplate 10 for a reticle pod. FIG. 2 shows the top 12 of the baseplate 10. The cover 40 is configured to be placed onto the top 12 of the baseplate 10. The baseplate 10 can also include the reticle supports 7A.

The baseplate 10 includes the seal surface 14 and a baseplate body 16. The seal surface 14 is formed on the baseplate body 16. The configuration of the seal surface 14 and the baseplate body 16 is described below in more detail. The baseplate 10 in FIG. 2 includes a single continuous seal surface 14. The seal surface 14 extends along the entire perimeter of the baseplate 10. However, the baseplate 10 may include multiple seal surfaces in an embodiment. For example, separate seal surfaces 14 can be provided at locations where greater amounts of wear may occur between the baseplate 10 and the cover 40. In an embodiment, the seal surface(s) 14 of the baseplate 10 may only extend along a portion of the perimeter of the baseplate 10.

As shown in FIG. 2, the one or more seal surfaces 14 are disposed so as to cover less than 75% of the baseplate 10. In an embodiment, the one or more seal surfaces 14 are disposed so as to cover less than 50% of the baseplate 10.

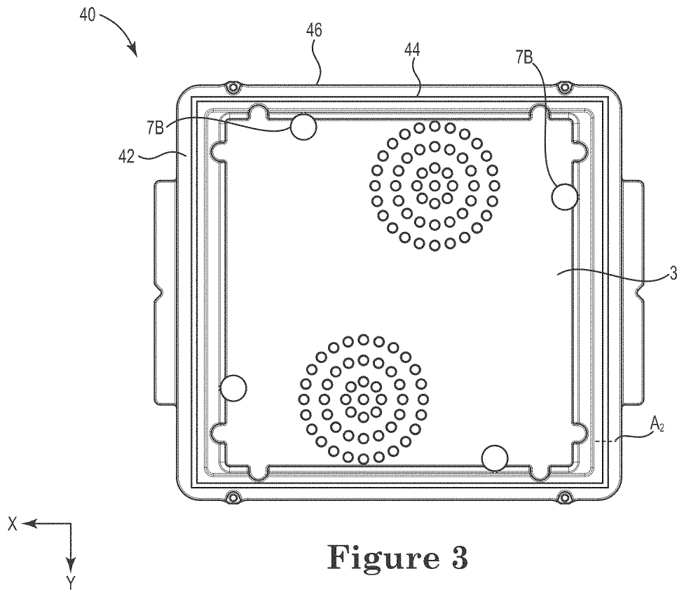

FIG. 3 is a bottom view of an embodiment of the cover 40 for an inner pod. FIG. 3 shows the bottom 42 of the cover 40. The bottom 42 of the cover 40 is configured to contact the top 12 of the baseplate 40 when the cover 40 is placed on the baseplate 10. The cover 40 can also include the reticle containment portion 3 and the reticle contacts 7B that contact an upper surface of the reticle within the inner pod.

The cover 40 includes the seal surface 44 and a cover body 46. The seal surface 44 is formed on the cover body 46. The configuration of the seal surface 44 and the cover body 46 is described below in more detail. The cover 40 in FIG. 3 includes a single continuous seal surface 44. However, the cover 40 may include multiple seal surfaces in an embodiment. For example, each of the seal surfaces 44 only extending along a portion of the perimeter of the base plate 40. For example, the separate seal surfaces 44 may be provided at locations in which a greater amount of wear occurs between the baseplate 10 and the cover 40.

The seal surface 44 extends along the entire perimeter of the cover 40. Accordingly, when the cover 40 is placed on the baseplate 10, the seal surface 44 is disposed so as to extend along the entire perimeter of the baseplate 10. In some embodiments, the one or more seal surfaces 14 of the baseplate 10 and the one or more seal surfaces 44 of the cover 40 may be disposed so as to extend around the entire perimeter of the baseplate 10 in combination. For example, the seal surface(s) 14 of the baseplate 10 may not extend along the entire perimeter of the baseplate 10, and the seal surface(s) 44 of the cover 40 extend along the portion(s) of the perimeter of the baseplate 10 without the seal surface(s) 14. When considered in combination, the seal surface(s) 14 of the baseplate 10 and the seal surfaces 44 of the cover 40 can extend along the entire perimeter of the baseplate 10.

The seal surface(s) 44 are provided so as to cover less than 75% of the cover 40. In an embodiment, the seal surface(s) 44 cover less than 50% of the cover 40. The seal surface(s) 14, 44 of the inner pod 1 are formed so as to cover less than 75% of the baseplate 10 and the cover 40. In an embodiment, the seal surface(s) 14, 44 are formed so as to cover less than 50% of the baseplate 10 and the cover 40.

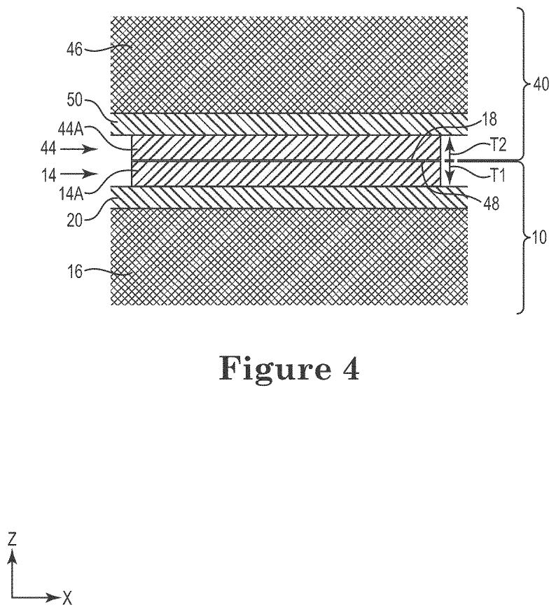

FIG. 4 is a cross-sectional view across the seal surfaces 14, 44 of the baseplate 10 and the cover 40. For example, the cross-section in FIG. 4 extends through the dashed line A₁ in FIG. 2 and the dashed line A₂ in FIG. 3. FIG. 4 shows a structure and interaction of a seal surfaces 14, 44 when the cover 40 is placed on the baseplate 10 (e.g., as shown in FIG. 1B).

The seal surface 14 is formed on the baseplate body 16, and the seal surface 44 is formed on the cover body 46. The baseplate body 16 and the cover body 46 are respectively formed of metal. The baseplate body 16 and the cover body 46 can be formed of the same metal. In an embodiment, the baseplate body 16 includes aluminum and the seal surface 14 is formed on the aluminum of the baseplate body 16. In an embodiment, the cover body 46 includes aluminum and the seal surface 44 is formed on the aluminum of the cover body 46.

Each seal surface 14, 44 includes a wear-resistant outermost coating 14A, 44A. Each wear-resistant outermost coating 14A, 44A extends along the entire length of its seal surface 14, 14. For example, the wear-resistant outermost coating 14A would extend along the entire perimeter of the baseplate 12 as similarly described above and shown in FIG. 2 for the sealing surface 14.

Returning to FIG. 4, along each seal surface 14 of the baseplate 10, a wear-resistant outermost coating 14A provides the outer surface 18 of the baseplate 10. Along each seal surface 44 of the cover 40, the wear-resistant outmost coating 44A provides the outer surface 48 of the cover 40. Accordingly, the cover 40 when placed on the baseplate 10 only contacts the baseplate 10 via one or more wear-resistant outermost surfaces 14A, 44A.

Each wear-resistant outermost coating 14A, 44A has a Rockwell C hardness of about or greater than 70. Rockwell C hardness is measured and determined according to ASTM E18-20. In an embodiment, the wear-resistant outermost coating 14A, 44A has a Rockwell C hardness of about or greater than 80. For example, the wear-resistant coating 14A and/or 44A may be, but is not limited to, titanium nitride, chromium nitride, diamond-like carbon, and diamond nickel composite. In one embodiment, the wear-resistant coating 14A and/or 44A is a diamond nickel composite. In another embodiment, the wear resistant coating 14A and/or 44A is diamond-like carbon. In still other embodiments, the wear-resistant coating 14A and/or 44A titanium nitride or chromium nitride. Wear resistant coatings incorporating cobalt or cobalt composites having a Rockwell C hardness of about or greater than 70 are also contemplated.

The wear-resistant outermost coating 14A, 44A has a thickness T₁, T₂ that is smaller than the thickness of the baseplate body 16 or the cover body 46 on which its formed. In an embodiment, the thickness of a wear-resistant outermost coating 14A, 44A is about 0.1 to about 100 micrometers. In an embodiment, the thickness of a wear-resistant outermost coating 14A, 44A is about 0.1 to about 60 micrometers. In an embodiment, a thickness of a wear-resistant outermost coating 14, 44A is about 0.1 to about 40 micrometers. Depending on the application, seal surface 14 of the baseplate 10 can a wear-resistant outermost coating 14A that can be the same or different than the wear-resistant outermost coating 44A that is provided on the seal surface 44 of the cover.

As shown in FIG. 4, an inner layer 20 is provided between the wear-resistant outermost coating 14A and the baseplate body 16. The inner layer 20 is formed on the baseplate body 16, and the wear-resistant outermost coating 14A is on the stacked inner layer 20 and baseplate body 16. For example, the inner layer 20 may be, but is not limited to, nickel. In an embodiment, the baseplate 10 may not include the inner layer 20. For example, the wear-resistant outermost coating 14A may be formed directly on the material of the baseplate body 16. In another embodiment, a plurality of inner layers 20 may be provided between the wear-resistant outermost coating 14A and the baseplate body 16. For example, the baseplate body 16 may include inner layer(s) 20 that improves one or more properties of the baseplate 10 (e.g., decreased reactivity, increased strength, etc.), and/or one or more properties of the wear-resistant outermost coating 14A (e.g., increased strength, increased adhesion of the wear-resistant outermost coating, etc.). In an embodiment, the cover 40 may include an inner layer 50 in a similar manner as described above.

In FIGS. 1A-4, both the baseplate 10 and the cover 40 are provided with at least one seal surface 14, 44 that has a wear-resistant outermost coating 14A, 44A. The seal surface 14 of the baseplate 10 directly contacts the seal surface 44 of the cover 40. More particularly, the wear-resistant outermost coating 14A of the baseplate 10 directly contacts the wear-resistant outermost coating 44A of the cover 40. In other embodiments, a seal surface and its wear-resistant outermost coating may not contact the wear-resistant outermost coating of an opposing seal surface. The seal surface 14, 44 and its wear-resistant outermost coating 14A, 44A may directly contact a material other than a wear-resistant outermost coating. For example, a seal surface 14, 44 and its wear-resistant outer coating 14A, 44A may directly contact the metal of the opposing baseplate body 16 or cover body 46, or a coating on said opposing baseplate body 16 or cover body (e.g., layer 20, layer 50, etc.)

However, it should be appreciated that only one of the baseplate 10 and the cover 40 may have seal surface(s) in some embodiments. For example, the cover 40 may be provided with one or more seal surfaces 44 while the baseplate 10 does not include any seal surfaces, or vis-versa. In such a configuration, a wear-resistant outermost coating 44A of the cover 40 would contact a different material of the baseplate 10 (e.g., a metal of the baseplate body 16, the layer 20, etc.).

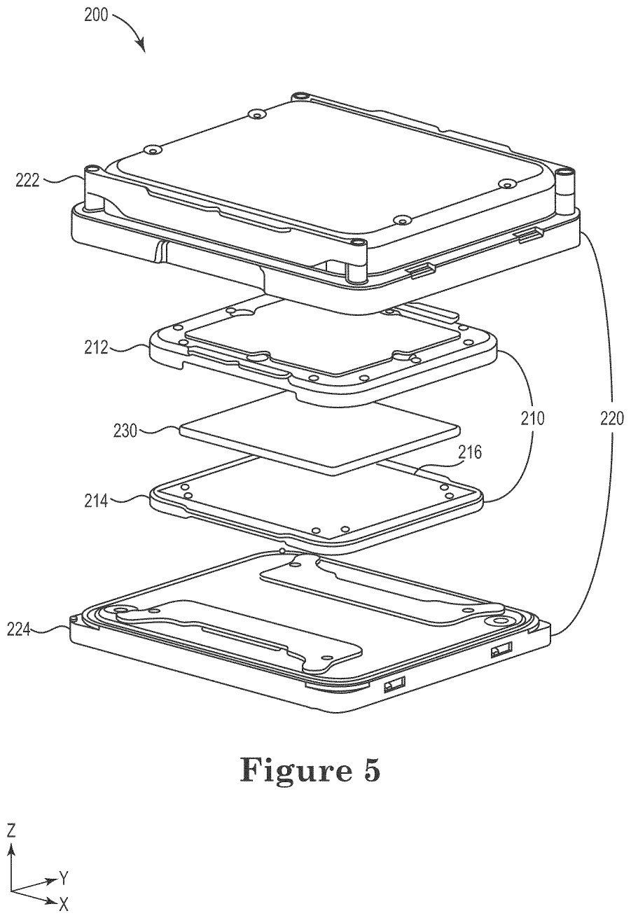

FIG. 5 is a prospective view of a reticle pod 200, according to an embodiment. The reticle pod 200 includes an inner pod 210 and an outer pod 220. For example, the reticle pod 200 can be, but is not limited to, a reticle pod for extreme ultraviolet (“EUV”) processing of photolithography masks.

The inner pod 210 includes a cover 212 and a baseplate 214. The cover 212 and the baseplate 214 are configured to be joined together. When joined together, the cover 212 and the baseplate 214 define an internal space sized and shaped contain a reticle 230 for use. For example, the reticle 230 can be, but is not limited to, a photolithography mask that will be used in extreme ultraviolet (EUV) processing. In some embodiments, at least one of the cover 212 and the baseplate 214 include one or more seal surfaces 216 as similarly discussed above for the baseplate 10 and cover 40 in FIGS. 1A-3. In some embodiments, the cover 212 and the baseplate 214 each include at least one of the seal surfaces 216 (obscured in FIG. 5 for the cover 212). Each of the seal surfaces 216 including a wear-resistant outermost coating. The wear-resistant outermost coating can be, for example, the wear-resistant outermost coating 14A described above for FIG. 4. The cover 212 can be, for example, the cover 40 described above and shown in FIGS. 1A, 1B, and 3. The baseplate 214 can be, for example, the baseplate 10 described above and shown in FIGS. 1A, 1B, and 2.

The outer pod 220 includes an outer pod dome 222 and an outer pod door 224. The outer pod 220 is configured to accommodate the inner pod 210 within an internal space defined by the outer pod dome 222 and the outer pod door 224. The outer pod dome 222 can be secured to the outer pod door 224 to enclose the internal space and contain the inner pod 210, for example during transport and handling of the reticle pod 200. The outer pod dome 222 and the outer pod door 224 can each include or be made entirely of one or more polymer materials.

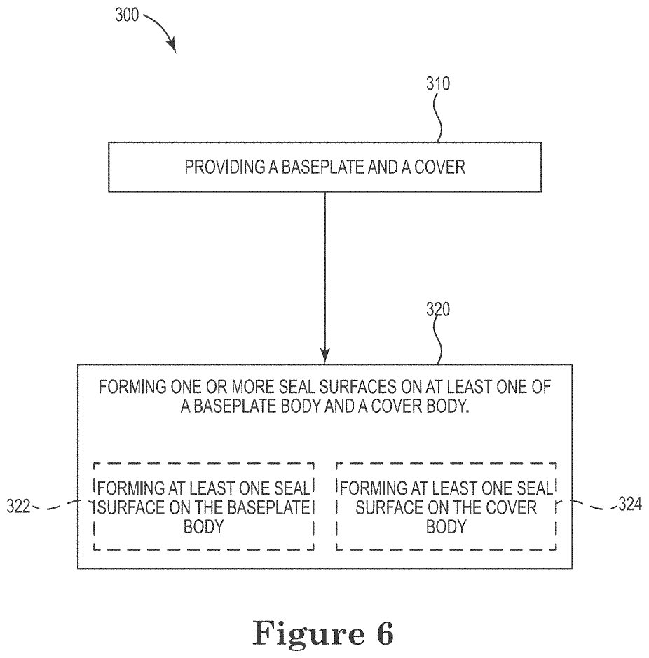

FIG. 6 is a block diagram for a method 300 of producing a reticle pod. For example, the method 300 may form reticle pod 300 as described above and in FIG. 5, or form one or both of the baseplate 10 and the cover 40 for a reticle pod described above and in FIGS. 1A-4. In an embodiment, the reticle pod is an EUV reticle pod. The method 300 starts at 310.

At 310, a baseplate (e.g., baseplate 10, baseplate 214) and a cover (e.g., cover 40, cover 212) for a reticle pod are provided. In an embodiment, 310 may include forming one or both of the baseplate and the cover. The method 300 then proceeds to 320.

At 320, one or more seal surfaces (e.g., seal surface 14, seal surface 44, seal surface 216) are formed on at least one of a baseplate body of the baseplate (e.g., baseplate body 16) and a cover body of the cover (e.g., cover body 46). The one or more seal surfaces are configured to provide sealing between the baseplate and the cover. Each of the one or more seal surfaces includes a wear-resistant outermost coating (e.g., wear-resistant outermost coating 14A, wear-resistant outermost coating 44A) that has a Rockwell C hardness of about or greater than 70. Non-limiting examples of how the wear-resistant outermost coating(s) may be formed include physical vapor deposition, sputter deposition, chemical vapor deposition, and plasma-enhanced chemical vapor deposition.

In an embodiment, forming the one or more seal surfaces 320 includes forming a seal surface on the baseplate body 322. Forming the seal surface on the baseplate body 322 would include forming a wear-resistant outermost coating on the baseplate body (e.g., wear-resistant outermost coating 14A). The wear-resistant outermost coating is disposed on the baseplate body so as to directly contact the cover when the cover is placed on the baseplate.

In an embodiment, forming the one or more seal surfaces 320 includes forming at least one seal surface on the cover body 324. Forming the seal surface on the cover body 324 would include forming a wear-resistant outermost coating on the cover body (e.g., wear-resistant outermost coating 44A). The wear-resistant outermost coating is disposed on the cover body so as to directly contact the baseplate when the cover is placed on the baseplate.

In some embodiments, forming one or more seal surfaces 320 includes both forming the seal surface on the baseplate body 322 and forming the seal surface on the cover body 324. In other embodiments, forming one or more seal surfaces 220 can only include one of forming the seal surface on the baseplate body 322 or forming the seal surface on the cover body 324.

In some cases, following their formation, the wear-resistant outermost coating(s) can be polished to a desired surface roughness or smoothness to enhance the contact surface area and to minimize surface defects in the wear-resistant coatings(s).

It should be appreciated that the method 300 in various embodiments may be modified to achieve feature(s) comparable to those discussed above with respect to the baseplate 10 and cover 40 in FIGS. 1A-4. For example, the method 300 in an embodiment may form the one or more seal surfaces 320 so as to extend along an entire perimeter of the baseplate.

Aspects:

Any of aspects 1-12 can be combined with any of aspects 13-20.

Aspect 1. A pod comprising: a cover including a cover body; a baseplate including a baseplate body; and one or more seal surfaces formed on one or more of the baseplate body and the cover body to provide sealing between the cover and the baseplate, the one or more seal surfaces each including a wear-resistant outermost coating with a Rockwell C hardness of about or greater than 70.

Aspect 2. The pod of aspect 1, wherein the Rockwell C hardness of the wear-resistant outermost coating is about or greater than 80.

Aspect 3. The pod of aspect 1 or 2, wherein the wear-resistant outermost coating is one of titanium nitride, chromium nitride, and diamond-like carbon.

Aspect 4. The pod of any one of aspects 1-3, wherein the wear-resistant outermost coating has a thickness of about 0.1 to about 100 micrometers.

Aspect 5. The pod of any one of aspects 1-4, wherein the one or more seal surfaces cover less than 75% of the baseplate and less than 75% of the cover.

Aspect 6. The pod of any one of aspects 1-4, wherein the one or more seal surfaces include a first seal surface formed on the baseplate body, the baseplate including the wear-resistant outermost coating of the first seal surface, the wear-resistant outermost coating of the first seal surface disposed to directly contact the cover when the cover is placed on the baseplate.

Aspect 7. The pod of aspect 6, wherein the baseplate body includes aluminum, the wear-resistant outermost coating formed on the aluminum.

Aspect 8. The pod of aspect 6 or 7, wherein the one or more seal surfaces include a second seal surface formed on the cover body, the cover including the wear-resistant outermost coating of the second seal surface, the wear-resistant outermost coating of the cover disposed to directly contact the wear-resistant outermost coating of the baseplate when the cover is placed on the baseplate.

Aspect 9. The pod of any one of aspects 1-8, wherein the cover, when placed on the baseplate, only contacts the baseplate via the one or more wear-resistant outermost surfaces of the one or more seal surfaces.

Aspect 10. The pod of any one of aspects 1-9, wherein the one or more wear-resistant outer surfaces of the one or more seal surfaces extend along an entire perimeter of the baseplate.

Aspect 11. The pod of any one of aspects 1-9, wherein the pod is a EUV reticle pod.

Aspect 12. The pod of any one of aspects 1-11, further comprising: an outer pod dome and an outer pod door, the outer pod dome and the outer pod door configured to accommodate the baseplate and the cover within the outer pod dome when the outer pod door is attached to the outer pod dome.

Aspect 13. A method of producing a reticle pod, comprising: forming one or more seal surfaces on at least one of a baseplate body of a baseplate and a cover body of a cover to provide sealing between the baseplate and the cover, the one or more seal surfaces each including a wear-resistant outermost coating with a Rockwell C hardness of about or greater than 70.

Aspect 14. The method of aspect 13, wherein the Rockwell C hardness of the wear-resistant outermost coating is about or greater than 80.

Aspect 15. The method of aspect 13 or 14, wherein the wear-resistant outermost coating is one of titanium nitride, chromium nitride, and diamond-like carbon.

Aspect 16. The method of any one of aspects 13-15, wherein the wear-resistant outermost coating has a thickness of about 0.1 to about 100 micrometers.

Aspect 17. The method of any one of aspects 13-16, wherein forming the one or more seal surfaces on the at least one of the baseplate body and the cover body includes forming the one or more seal surfaces to cover less than 75% of the at least one of the baseplate and less than 75% of the cover.

Aspect 18. The method of any one of aspects 13-17, wherein the one or more seal surfaces include a first seal surface, and forming the one or more seal surfaces includes forming the wear-resistant outermost coating of the first seal surface on the baseplate body, the wear-resistant outermost coating of the first seal surface disposed to directly contact the cover when the cover is placed on the baseplate.

Aspect 19. The method of any one of aspects 13-18, wherein the baseplate body includes aluminum, and forming the one or more seal surfaces includes forming the wear-resistant outermost coating of the first seal surface on the aluminum of the baseplate.

Aspect 20. The method of any one of aspects 13-19, wherein forming the one or more seal surfaces includes forming the one or more wear-resistant outer surfaces of the one or more seal surfaces to extend along an entire perimeter of the baseplate.

The examples disclosed in this application are to be considered in all respects as illustrative and not limitative. The scope of the disclosure is indicated by the appended claims rather than by the foregoing description; and all changes which come within the meaning and range of equivalency of the claims are intended to be embraced therein.

What is claimed is:

1. A pod comprising:
a cover including a cover body;
a baseplate including a baseplate body; and
one or more seal surfaces formed on one or more of the baseplate body and the cover body to provide sealing between the cover and the baseplate, the one or more seal surfaces each including a wear-resistant outermost coating with a Rockwell C hardness of about or greater than 70.

2. The pod of claim 1, wherein the Rockwell C hardness of the wear-resistant outermost coating is about or greater than 80.

3. The pod of claim 1, wherein the wear-resistant outermost coating is one of titanium nitride, chromium nitride, diamond-like carbon, or diamond-nickel composite.

4. The pod of claim 1, comprising a first seal surface having a first wear-resistant outermost coating is formed on the baseplate body and a second seal surface having a second wear-resistant outermost coating formed on the cover body, wherein the first wear-resistant outermost coating is the same as the second wear-resistant outermost coating.

5. The pod of claim 1, comprising a first seal surface having a first wear-resistant outermost coating is formed on the baseplate body and a second seal surface having a second wear-resistant outermost coating formed on the cover body, wherein the first wear-resistant outermost coating is different from the second wear-resistant outermost coating.

6. The pod of claim 1, wherein the one or more seal surfaces include a first seal surface formed on the baseplate body, the baseplate including the wear-resistant outermost coating of the first seal surface, the wear-resistant outermost coating of the first seal surface disposed to directly contact the cover when the cover is placed on the baseplate.

7. The pod of claim 6, wherein the baseplate body includes aluminum, the wear-resistant outermost coating formed on the aluminum.

8. The pod of claim 6, wherein the one or more seal surfaces include a second seal surface formed on the cover body, the cover including the wear-resistant outermost coating of the second seal surface, the wear-resistant outermost coating of the cover disposed to directly contact the wear-resistant outermost coating of the baseplate when the cover is placed on the baseplate.

9. The pod of claim 1, wherein the cover, when placed on the baseplate, only contacts the baseplate via the one or more wear-resistant outermost surfaces of the one or more seal surfaces.

10. The pod of claim 1, wherein the one or more wear-resistant outer surfaces of the one or more seal surfaces extend along an entire perimeter of the baseplate.

11. A method of producing a reticle pod, comprising:
forming one or more seal surfaces on at least one of a baseplate body of a baseplate and a cover body of a cover to provide sealing between the baseplate and the cover, the one or more seal surfaces each including a wear-resistant outermost coating with a Rockwell C hardness of about or greater than 70.

12. The method of claim 11, wherein the Rockwell C hardness of the wear-resistant outermost coating is about or greater than 80.

13. The method of claim 11, wherein the wear-resistant outermost coating is one of titanium nitride, chromium nitride, diamond-like carbon, or diamond-nickel composite.

14. The method of claim 11, wherein the wear-resistant outermost coating has a thickness of about 0.1 to about 100 micrometers.

15. The method of claim 11, wherein forming the one or more seal surfaces on the at least one of the baseplate body and the cover body includes forming the one or more seal surfaces to cover less than 75% of the at least one of the baseplate and less than 75% of the cover.

16. The method of claim 11, wherein
the one or more seal surfaces include a first seal surface, and
forming the one or more seal surfaces includes forming the wear-resistant outermost coating of the first seal surface on the baseplate body, the wear-resistant outermost coating of the first seal surface disposed to directly contact the cover when the cover is placed on the baseplate.

17. The method of claim 16, wherein
the baseplate body includes aluminum, and
forming the one or more seal surfaces includes forming the wear-resistant outermost coating of the first seal surface on the aluminum of the baseplate.

18. The method of claim 11, wherein forming the one or more seal surfaces includes forming the one or more wear-resistant outer surfaces of the one or more seal surfaces to extend along an entire perimeter of the baseplate.
